(19) United States
(12) Patent Application Publication
(10) Pub. No.: US 2004/0135594 A1
(43) Pub. Date: Jul. 15, 2004

(54) Compliant interposer assembly for wafer test and "burn-in" operations

(76) Inventors: Brian Samuel Beaman, Cary, NC (US); Keith Edward Fogel, Mohegan Lake, NY (US); Paul Alfred Lauro, Brewster, NY (US); Da-Yuan Shih, Poughkeepsie, NY (US)

Correspondence Address: Alvin J. Riddles, Box 34, Candlewood Isle, New Fairfield, CT, 06812, US

(21) Appl. No.: 10/341,794

(22) Filed: Jan. 14, 2003

(51) Int. Cl. G01R 31/26

(52) U.S. Cl. 324/765

(57) ABSTRACT

In the invention a compliant interposer is provided that accommodates variations in contact height, contact location, and contact materials. The interposer is in direct contact in the interface between the contact surface of the IC under test and the fan out wiring surface of the test equipment and which carries interconnection ability that is compliant with respect to the interfaces. The interposer has structurally parallel contacting layers that are compressively held apart at a separation distance by a fame member that in turn has areas in which interconnect members can move in accommodating spatial variations in the IC and fan out contacts in the interface. Each layer of the interposer, that is to be in contact with the IC contacts and with the fan out contacts has comparable a pattern of holes for each end region of each interconnect conductor members. Those interconnect conductor members in turn send from each IC contact through one of the holes in the pattern in the IC interposer layer that is adjacent to the IC, pass through a bend in the movement area of the frame and then out through a corresponding hole in the pattern in the interposer layer adjacent to the fan out. Compliant capability is thus built into the interposer contact layers for adaptability at each interface.

### FIELD OF THE INVENTION

The invention is directed to the testing of electrical devices of the integrated circuit, component, or multi chip module type and in particular to probe or contacting tools for use in the testing and “burn-in” operations in the fabrication of such devices.

### BACKGROUND OF THE INVENTION

Integrated Circuit assemblies and other electronic components, hereinafter referred to as ICs, generally in wafer form, in the course of their fabrication, are tested to verify the electrical functioning of the device. In certain devices such a verification operation may also include a special testing operation, known as “burn-in” that is conducted under conditions that usually are beyond the normal use conditions for temperature and load for purposes of accelerating early life failures.

For silicon integrated circuit assemblies probing at the wafer level is typically done on a single chip site at temperatures ranging from 25 degrees C. to 125 degrees C. whereas the “burn in” type operation is usually done on diced and packaged chips at temperatures ranging from 80 degrees C. to 150 degrees C. For the recent technology progress; the wafer probing and integrated circuit chip “burn in” operations are being found to be beneficial when conducted at temperatures approaching 200 degrees C.

Simultaneous testing of multiple chips on a single wafer has obvious advantage for cost reduction and increased productivity and is expected to be a logical step towards testing and “burn-in” for an entire wafer.

The testing and “burn-in” operations are influenced by a large number of interrelated structural factors and techniques. The various types of interconnection methods used in such testing include permanent, semi-permanent and temporary attachment techniques. The permanent and semi-permanent techniques that are typically used include soldering and wire bonding to provide a connection from the IC device to a substrate with fan out wiring or a metal lead frame package.

The temporary attachment techniques include rigid and flexible probes that are used to connect the IC device to a substrate with fan out wiring or directly to the test equipment.

The permanent attachment techniques used for testing integrated circuit devices such as wire bonding to a lead frame of a plastic lead frame chip carrier are typically used for devices that have a low number of interconnections and the plastic lead frame chip carrier package is relatively inexpensive. The device is tested through the wire bonds and leads of the plastic carrier and plugged into a test socket. If the integrated circuit device is defective, the device and the plastic carrier are discarded.

The semi permanent attachment techniques used for testing integrated circuit devices such as solder ball attachment to a ceramic or plastic pin grid array package are typically used for devices that have a high number of interconnections and the pin grid array package is relatively expensive. The device is tested through the solder balls and the internal fan out wiring and pins of the pin grid array package that is plugged into a test socket. If the integrated circuit device is defective, the device can be removed from the pin grid array package by heating the solder balls to their melting point. The processing cost of heating and removing the chip is offset by the cost saving of reusing the pin grid array package.

The more cost effective techniques for testing and “burn in” of integrated circuit devices provide direct interconnection between pads on the device to a probe socket that is directly connected to the test equipment. Contemporary probes for testing integrated circuits are expensive to fabricate and are easily damaged. The individual probes are typically attached to a ring shaped printed circuit board and support cantilevered metal wires extending towards the center of the opening in the circuit board. Each probe wire must be aligned to a contact location on the integrated circuit device to be tested. The probe wires are generally fragile and easily deformed or damaged. This type of probe fixture is typically used for testing integrated circuit devices that have contacts along the perimeter of the device. This type of probe is also much larger than the IC device that is being tested and the use of this type of probe for high temperature testing is limited by the probe structure and material set.

Another technique used for testing IC devices employs a thin flex circuit with metal bumps and fan out wiring. The bumps are typically formed by photo lithographic processes and provide a raised contact for the probe assembly. The bumps are used to contact the flat or recessed bond pads usually made of aluminum on the IC device. An elastomer pad is typically used between the back of the flex circuit and a pressure plate or rigid circuit board to provide compliance for the probe interface. This type of probe is limited to flexible film substrate materials that typically have one or two wiring layers.

The position of the probe tips requires control to insure accurate alignment of the probes to the interconnection pads on the IC device. During high temperature “burn in” testing, the thermal expansion mismatch between the probe structure and the IC device must be small to ensure that the probe position does not vary significantly over the burn in temperature range. Thermal expansion mismatch within the probe can result in contact reliability problems.

The challenges of probing a single high density integrated circuit device are further multiplied for multi-chip and full wafer testing applications.

Probe fabrication techniques and material selection are critical to the thermal expansion and contact alignment considerations. A small difference in the thermal expansion of the substrate, wafer and probe construction will cause misalignment of the probe tip to the contact pads on the wafer.

Compliance of the probe structure is another critical factor. Slight variations in the wafer metallization, passivation, warpage of the wafer, and sight variations in the probe height contribute to the total compliance requirements for the probe structure. An ability to build compliance for these considerations in any probe interface is desirable.

Repair of a damaged probe contact or replacement of a worn probe becomes a key concern for multi-chip and full wafer testing applications. It may be very expensive or time consuming to replace a probe on a test fixture used to test multiple IC devices on a single wafer. A segmented interposer construction can assist by providing a means of replacing a portion of the probes in the test fixture without affecting the remaining probes or test substrate.

A further challenge involves controlled impedance electrical characteristics in testing high frequency signal connections. Many interconnection systems use a one to one arrangement of signal and ground connections to approximate a controlled impedance interface. Such an approach reduces the effective number of signal connections that can be used on an IC device. An ability to have coaxial conductors provides a superior means of impedance control as well as reducing the coupled noise between signal conductors, without reducing the effective number of signal connections that can be used on an IC device.

Attention in the art is being given to provide accommodation in the test apparatus to address some of the limitations being encountered. At present some compliance has been built into a limited interposer construction where the contacts are solder balls and wire bond pads involving a special alloy known in the art as Paleny 7 mounted in a machined housing. Adaptability is limited however where an intermediate structure such as a housing is involved. Further, where the length of the wires in the probe approach 150-250 mils undesirable inductance electrical characteristics and crosstalk coupling are being encountered.

There is a need developing in the art for a testing and “burn in” interface that is compliant so as to ease more of the many considerations in the present technology such as spacing contact level and material compatibility.

### SUMMARY OF THE INVENTION

In the invention a compliant interposer is provided that accommodates variations in contact height, contact location, and contact materials. The interposer is in direct contact in the interface between the contact surface of the IC under test and the fan out wiring surface of the test equipment and which carries interconnection ability that is compliant with respect to the interfaces. The interposer has structurally parallel contacting layers that are compressively held apart at a separation distance by a frame member that in turn has areas in which interconnect members can move in accommodating spatial variations in the IC and fan out contacts in the interface. Each layer of the interposer, that is to be in contact with the IC contacts and with the fan out contacts, has comparable a pattern of holes for each end region of each interconnect conductor members. Those interconnect conductor members in turn extend from each IC contact through one of the holes in the pattern in the IC interposer layer that is adjacent to the IC, pass through a bend in the movement area of the frame and then out through a corresponding hole in the pattern in the interposer layer adjacent to the fan out. Compliant capability is thus built into the interposer contact layers for adaptability at each interface.

### BRIEF DESCRIPTION OF THE DRAWINGS

FIG. 1 is a schematic cross sectional depiction illustrating some variables in height and spacing to be accommodated in the relative superimposed positioning of the IC element under test and the equipment fan out wiring.

FIG. 2 is a schematic cross sectional view of the compliant interposer of the invention compressively positioned at the interface between an IC and a fan out testing equipment input.

### DESCRIPTION OF THE INVENTION

In accordance with the invention an accommodation for a number of the variations in positioning contact height and contact materials on the two interface levels, the IC to interposer interface and the interposer to test equipment fan out pattern interface, is achieved through the providing of a compliant interposer structure compressively positioned between the IC contact pattern and the fan out contact pattern of the test equipment; the individual contacts in the patterns being joined in the interposer structure with curved signal conductors that accommodate contact spacing and contact height variations. In the invention, the compliant interposer structure provides superimposed parallel location patterns for signal interconnect transmitting conductors in which physical movability built into the interconnect conductors can compensate for registration variations when the IC and test equipment fan out patterns are aligned and can further compensate for different contact levels in the two interfaces.

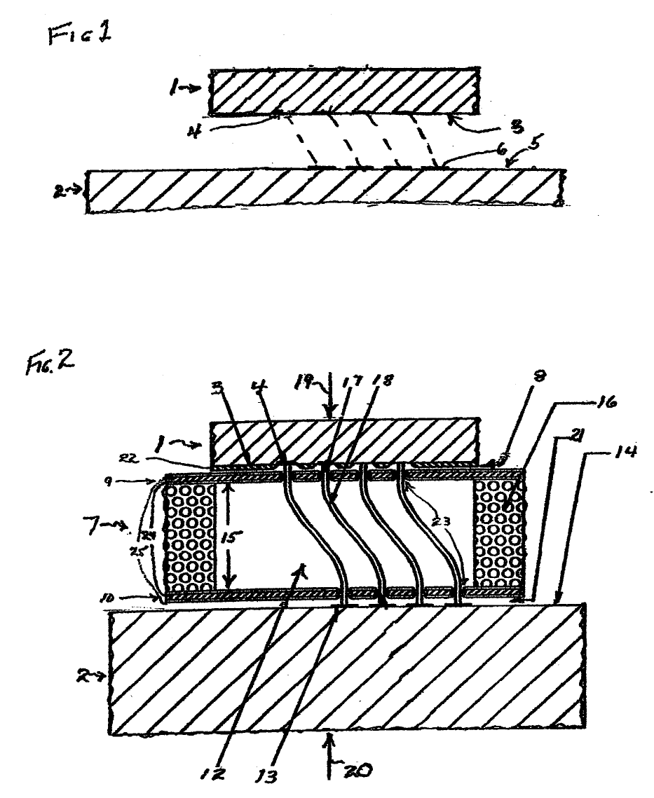

The nature of the accommodation that will be needed is illustrated in connection with FIG. 1 wherein there is shown a schematic cross sectional depiction of the superimposed positioning of exemplary four contact and wiring interconnect portions of an IC element to be tested and a corresponding four contact portion of a board supporting the the input and output fan out wiring of the test equipment, as would occur during a testing or “burn-in” operation.

Referring to FIG. 1; the portion of the IC under test is labelled element 1 and the portion of the board supporting the input and output fan out wiring is labelled element 2. The IC 1 interface surface labelled element 3 has at that surface, input-output pads 4 of which four are shown. The board 2 has, on an interface surface labelled element 5, fan out wiring pads labelled element 6 of which four are shown. There are illustrative dotted lines between individual pads and contacts indicating displacement which would require compliance. The point being made here is that in fabrication operations the formation of good reliable and repeatable connections in arrays of pads and contacts require compliance with respect to horizontal tolerances, vertical tolerances and electrical tolerances such as impedance caused by oxidation or other of to the contacting metal set.

In FIG. 2 there is shown a schematic cross sectional view of the compliant interposer of the invention compressively positioned at the interface between the IC, element 1 and the fan out board, element 2, the input to the testing equipment.

Referring to FIG. 2 a compliant interposer 7 of the invention is positioned in a stack between the IC 1 and the board 2.

In the IC 1 the input-output contacts 4, of which an exemplary four are shown are shown, are positioned at the surface 3 of the IC 1 at the interface 8 with the compliant interposer 7.

In considering the stack in FIG. 2 made up of the IC element 1 at the interface 8 contacting the compliant interposer element 7 and in turn contacting the fan out input wiring board element 2; the interposer 7 structure includes external layers 9 and 10, each having a pattern of holes through the respective layer 9 and 10 in the configuration of the pads 4 on the adjacent surface 3 of the IC 1 and the configuration of the pads 13 on the surface 14 of the wiring board 2. The layers 9 and 10 are supported, in their spaced apart relationship enclosing an area 12, by a frame member 16, that maintains them at the separation distance 15. The interposer 7 further includes curved conductors 17 joining each of the pads 4 to the pads 13. The conductors 17 each passes through a pair of respective configuration pattern holes in the layers 9 and 10 and each has a bend or curved region 18 within the area 12.

The fan out substrate 2 provides a means of fanning out the wiring from the contacts 13 on the surface 14 to the equipment used in testing and burn in of the IC 1. The fan out substrate 2 can be made from various materials and constructions including single and multilayer ceramic with thick or thin film wiring, or epoxy glass laminate construction with high density copper wiring. The contacts 13 are usually flush with the surface 14 while the bond pads 4 on the IC 1 which usually are of aluminum are typically recessed sightly below a surface passivation layer 22 on the surface 3 of the IC 1.

In the testing operation the IC element 1 and the board element 2 are compressed on the interposer 7 by opposing forces 19 and 20 that close any gaps at interfaces 8 and 21 and each conductor 17 can accommodate differences in the level of pads 4 and 13 by movement in the area 12 at the bend 18. The compliant interposer 7 is compressed between the fanout substrate 2 and the IC 1 with each end of each of the curved interconnect wires 17 making contact to it's respective pad 13. The interconnect wires 17 pass through the pattern of holes in the layers 9 and 10 which serve as alignment masks. The frame 16 maintains separation of the layers 9 and 10. The ends of the interconnect wires 17 under compression are free to adjust contact pressure through the bend 18 in the area 12 to provide compliance and accommodation of differences in pad level.

The layers 9 and 10 with their patterns of holes 23 serving as alignment masks, may be made from a thin sheet of metal 24 such as Invar, each covered with a thin layer 25 of insulating material which is to electrically isolate each of the interconnect wires 17 and to provide a close match to the thermal expansion coefficient of the IC1. The diameter of the holes 23 in each metal sheet portion of the layers 9 and 10 respectively are only slightly larger than the diameter of the interconnect wires 17 and may be formed by precision chemical etching. The construction of the layers 9 and 10 further shows the insulating material 25 covering the top and bottom surfaces of the Invar sheet as well as the inside of each of the pattern of holes through which the interconnect wires 17 pass. The insulating material 25 can be an organic taken from the group of organic insulators known in the art such as polyimide, epoxy and parylene or an inorganic such as metal oxide, silicon oxide and nitride. The thin Invar sheet covered with the thin insulator matches the thermal expansion coefficient (TEC) of silicon up to about 180 degrees C. If the test temperature is lower than 100 degrees C. other metals such as molybdenum or non-metal materials such as those with the trade name Melcor or Vespal or further ceramics can be substituted for the Invar layer.

It will be apparent that the technology is very flexible and that flexibility can be brought to bear in the selection of materials and arrangement of the elements of the invention.

The function of the compliant interposer 7 of the invention is to overcome tolerance variations and to transfer the information needed for the testing being undertaken between the from the IC 1 and the test equipment and some structural modifications may be within the skill in the art. For one example the conductors 17, as frequency requirement become tighter may benefit from coaxial transmission which can be readily achieved by alternating deposition of metal and dielectic layers on the conductors 17 and contact location adjustment at surfaces 3 and 14. For another example the ball technology for reliable interconnection is well developed in the art and readily modifiable for the contacting of the ends of the conductors at the pads 4 and the contacts 13.

What has been described is an assembly and procedure for interfacing in the transfer of information between an integrated circuit and test equipment in which the interfacing provides compliance for differences in all directions.

What is claimed is:

1. In the transfer of information between integrated circuit input and output connections and test equipment input and output connections, the improvement for accommodating contact spacing and contact material variations between said input and output connections of said integrated circuit and said test equipment, comprising in combination:
an interfacing capability member having deformable interconnection members extending from an integrated circuit contacting array at a first of parallel faces to a test equipment contacting array at a second of said parallel faces and means for deforming said interconnection members between said faces.

2. The interfacing capability member of claim 1 wherein said interfacing member is compressively positioned between said integrated circuit input and output connections and said test equipment input and output connections and said first and second parallel faces are held apart by a spacer member having interconnection member deformability areas.

3. The interfacing capability member of claim 2 wherein said interfacing member is compressively positioned between said integrated circuit input and output connections and said test equipment input and output connections and the end of each interconnect member extends a deformation increment beyond said first and second parallel faces.

4. The interfacing capability member of claim 3 wherein said parallel faces of said interfacing member have an input and output configuration shaped array of interconnect member accommodating holes through a metal layer.

5. The interfacing capability member of claim 4 wherein said parallel faces of said interfacing member with an input and output configuration shaped array of interconnect member accommodating holes are through an insulation covered metal layer.

6. In a testing apparatus of the type having an integrated circuit with a face having an array of input-output pads and test equipment having a face with correlated input-output wiring terminals the improvement comprising:
means for compressively positioning a testing interposer between said integrated circuit face and said test equipment face,
said testing interposer having parallel faces each with a configuration of contact areas correlated with said input-output pads and terminal combinations,
said testing interposer having a deformable wire interconnecting member for each pad and terminal combination having an interconnecting member end extending beyond each said input-output pads and terminal combinations a deformations distance, and,
said testing interposer further having a deformation area between said faces through which each interconnect is positioned to pass.

7. The improvement of claim 6 wherein said parallel faces are each an insulated metal member with an array of correlated holes.

8. The improvement of claim 7 including an interconnect wire extending from each pad to said terminal in each combination.

9. In a testing apparatus of the type having a superimposed stack including in series
an integrated circuit member with a face having an array of input-output pads,
a testing interposer having a first face with a configuration of contact areas correlated with said input-output pads, and a second face with a configuration of test equipment input-output pads, and,
said testing interposer having means for accommodating spatial and level variations between said input-output pads and said test equipment input-output contacts.
